(19) United States
(12) Patent Application Publication
(10) Pub. No.: US 2025/0248290 A1
(43) Pub. Date: Jul. 31, 2025

(54) DISPLAY DEVICE

(71) Applicant: LG Display Co., Ltd., Seoul (KR)

(72) Inventors: Sungbin SHIM, Yangsan-si (KR); SangWon LEE, Paju-si (KR)

(73) Assignee: LG Display Co., Ltd., Seoul (KR)

(21) Appl. No.: 18/816,214

(22) Filed: Aug. 27, 2024

(30) Foreign Application Priority Data
Jan. 29, 2024 (KR) 10-2024-0013458

(51) Int. Cl. H10K 59/80; H10K 59/126; H10K 59/35; H10K 59/38

(52) U.S. Cl. CPC H10K 59/8792; H10K 59/126; H10K 59/35; H10K 59/38; H10K 59/878

(57) ABSTRACT

A display device may include a substrate, a plurality of sub-pixels each including an emission area, a first planarization layer disposed above the substrate, a second planarization layer which is disposed on the first planarization layer excluding a reflection hole which exposes the first planarization layer and is patterned for every sub-pixels, an anode which covers at least a part of the exposed first planarization layer and at least a part of the second planarization layer, a light shielding layer which covers a remaining part of the exposed first planarization layer, an organic layer disposed on the anode and the light shielding layer, and a cathode disposed on the organic layer. The light extraction efficiency is thus improved with an increase in the aperture ratio.

### CROSS-REFERENCE TO RELATED APPLICATIONS

This application claims the benefit of and priority to Korean Patent Application No. 10-2024-0013458 filed on Jan. 29, 2024, in the Korean Intellectual Property Office. The entire contents of the foregoing application are incorporated herein by reference for all purposes.

### BACKGROUND

### 1. Technical Field

The present disclosure relates to a display device, and more particularly, to a bottom emission type display device.

### 2. Description of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display (LCD) device, a field emission display (FED) device, an electro-wetting display (EWD) device, and an organic light emitting display (OLED) device.

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

The electroluminescent display device configures a light emitting diode by disposing a plurality of organic layers each including an emission layer between two electrodes of an anode electrode and a cathode electrode. For example, when holes are injected from the anode electrode into the emission layer and electrons are injected from the cathode electrode into the emission layer, the injected electrons and holes are recombined in the emission layer to form excitons and emit light.

However, the electroluminescent display device has a problem in that there is light which does not go out from a display panel to be trapped in the display panel, among light emitted from an emission layer so that a light extraction efficiency of the electroluminescent display device is degraded to degrade a luminous efficiency.

The description of the related art should not be assumed to be prior art merely because it is mentioned in or associated with this section. The description of the related art includes information that describes one or more aspects of the subject technology, and the description in this section does not limit the invention.

### SUMMARY

An object to be achieved by the present disclosure is to provide a display device which improves a light extraction efficiency and improves a rainbow mura.

Another object to be achieved by the present disclosure is to provide a display device in which a light extraction efficiency is improved and an aperture ratio is improved.

Still another object to be achieved by the present disclosure is to provide a display device which minimizes color mixture with surrounding sub-pixels.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device may include a substrate, a plurality of sub-pixels each including an emission area, a first planarization layer disposed above the substrate, a second planarization layer which is disposed on the first planarization layer excluding a reflection hole which exposes the first planarization layer, where the second planarization layer is patterned for every sub-pixels, an anode which covers at least a part of the exposed first planarization layer and at least a part of the second planarization layer, a light shielding layer which covers a remaining part of the exposed first planarization layer, an organic layer disposed on the anode and the light shielding layer and a cathode disposed on the organic layer.

According to another aspect of the present disclosure, a display device includes a substrate, a plurality of sub-pixels each including an emission area, a first planarization layer disposed above the substrate, a bank disposed on a first planarization layer of a non-emission area, a second planarization layer which is disposed on the first planarization layer to be spaced apart from the bank and is patterned for every sub-pixel, a reflection hole which exposes the first planarization layer between the bank and the second planarization layer, an anode which covers the exposed first planarization layer, a side surface and a part of a top surface of the bank, and a side surface and a top surface of the second planarization layer, an organic layer which is disposed on the anode and a remaining part of the top surface of the bank and a cathode disposed on the organic layer.

Other detailed matters of the example embodiments are included in the detailed description and the drawings.

According to the present disclosure, a reflection hole which encloses an emission area is disposed around an emission area and a cathode is used as a reflective electrode to improve a light extraction efficiency.

According to the present disclosure, at least two planarization layers having different refractive indexes are disposed below the light emitting diode and an interface is patterned in a micro lens shape to improve a light extraction efficiency without rainbow mura.

According to the present disclosure, instead of the bank, an anode extends to a side surface of the planarization layer thereon to be utilized as an internal total-reflection area to increase the aperture ratio and improve the light extraction efficiency. Accordingly, the low power is implemented to reduce the power consumption. Further, a green-house gas generated in accordance with the usage of the power is reduced to implement environment/social/governance (ESG).

According to the present disclosure, a light shielding layer is formed below the reflection hole to suppress color mixture with the surrounding sub-pixel.

The effects according to the present disclosure are not limited to the contents exemplified above, and more various effects are included in the present specification.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a block diagram for explaining a display device according to one or more example embodiments of the present disclosure;

FIG. 2 is a view schematically illustrating a circuit configuration of a sub-pixel according to one or more example embodiments of the present disclosure;

FIG. 3 is a view illustrating a cross-sectional structure and a planar structure of a display panel according to a first example embodiment of the present disclosure;

FIG. 4 is a view illustrating a cross-section of a part of a sub-pixel of FIG. 3;

FIG. 5 is a view illustrating a cross-sectional structure and a planar structure of a display panel according to a second example embodiment of the present disclosure;

FIG. 6 is a view illustrating a cross-section of a part of a sub-pixel of FIG. 5;

FIG. 7 is a view illustrating a cross-sectional structure and a planar structure of a display panel according to a third example embodiment of the present disclosure;

FIG. 8 is a view illustrating a cross-section of a part of a sub-pixel of FIG. 7;

FIG. 9 is a view illustrating a cross-sectional structure and a planar structure of a display panel according to a fourth example embodiment of the present disclosure;

FIG. 10 is a view illustrating a cross-section of a part of a sub-pixel of FIG. 9; and

FIG. 11 is a view illustrating a cross-sectional structure and a planar structure of a display panel according to a fifth example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, “at least a portion,” “at least portions,” “at least a part,” “at least parts,” or the like of an element can represent (i) a portion (or a part) of the element, (ii) one or more portions (or parts) of the element, or (iii) the element, or the entirety of the element.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an example embodiment of the present disclosure will be described in detail with reference to the drawings.

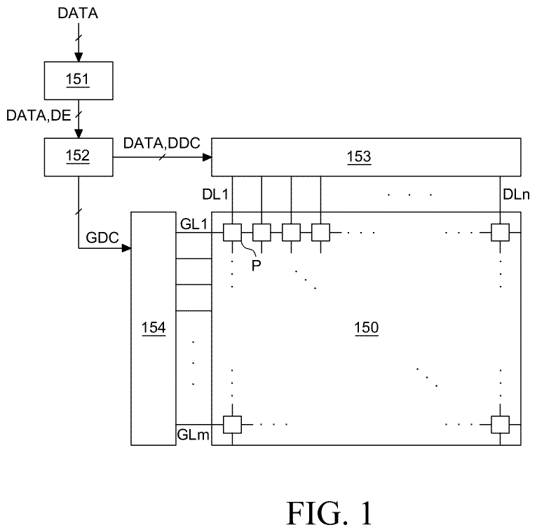

FIG. 1 is a block diagram for explaining a display device according to one or more example embodiments of the present disclosure.

Referring to FIG. 1, a display device according to one or more example embodiments of the present disclosure may include an image processor 151, a timing controller 152, a data driver 153, a scan driver 154, and a display panel 150.

The image processor 151 may output a data enable signal DE together with a data signal DATA supplied from the outside.

Further, for example, the image processor 151 may output one or more of a vertical synchronization signal, a horizontal synchronization signal, and a clock signal in addition to the data enable signal DE.

The timing controller 152 may be supplied with the data signal DATA together with the data enable signal DE or a driving signal including the vertical synchronization signal, the horizontal synchronization signal, and the clock signal from the image processor 151. Further, the timing controller 152 may output a gate timing control signal GDC for controlling an operation timing of the scan driver 154 and a data timing control signal DDC for controlling an operation timing of the data driver 153, based on the driving signal.

The data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn. The data driver 153 may be formed as an integrated circuit (IC).

Further, the scan driver 154 may output the scan signal in response to the gate timing control signal GDC supplied from the timing controller 152. The scan driver 154 may output the scan signal through gate lines GL1 to GLm. The scan driver 154 may be formed as an integrated circuit (IC) or formed in the display panel 150 in a gate in panel manner.

The display panel 150 may display images in response to the data signal DATA and the scan signal supplied from the data driver 153 and the scan driver 154.

The display panel 150 may include a sub-pixel SP which displays an image.

For example, the sub-pixel SP includes a red sub-pixel, a green sub-pixel, and a blue sub-pixel or may include a white sub-pixel, a red sub-pixel, a green sub-pixel, and a blue sub-pixel. The sub-pixel SP may have one or more emission areas according to an emission characteristic.

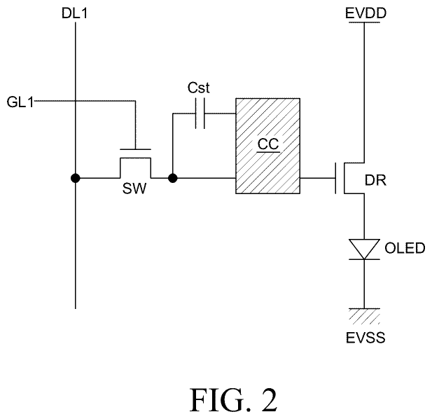

FIG. 2 is a view schematically illustrating a circuit configuration of a sub-pixel according to one or more example embodiments of the present disclosure.

Referring to FIG. 2, in one sub-pixel, a switching transistor SW, a driving transistor DR, a capacitor Cst, a compensation circuit CC, and an organic light emitting diode OLED may be included.

In this case, for example, the switching transistor SW may perform a switching operation such that a data signal supplied through a first data line DL1 is stored in a capacitor Cst as a data voltage in response to a scan signal supplied through a first gate line GL1. Further, for example, the driving transistor DR may operate to flow a driving current between a first power line EVDD (a high potential voltage) and a second power line EVSS (a low potential voltage) in accordance with the data voltage stored in the capacitor Cst. Further, the organic light emitting diode OLED may operate to emit light in accordance with a driving current formed by the driving transistor DR.

The compensation circuit CC is a circuit added in the sub-pixel to compensate for a threshold voltage of the driving transistor DR. The compensation circuit CC may be configured by one or more transistors. A configuration of the compensation circuit may vary depending on an external compensating method. For example, each sub-pixel structure is a 2T (transistor) 1C (capacitor) structure, but it is not limited thereto, so that the sub-pixel structure may further include one or more transistors and if necessary, further include one or more capacitors. Alternatively, the plurality of sub-pixels may have the same structure or some of the plurality of sub-pixels may have a different structure.

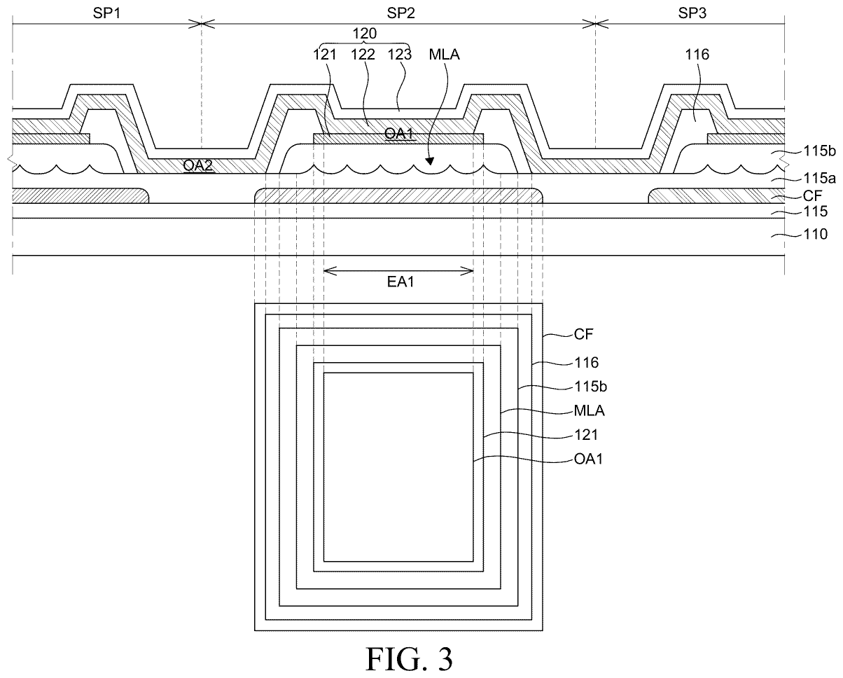

FIG. 3 is a view illustrating a cross-sectional structure and a planar structure of a display panel according to a first example embodiment of the present disclosure.

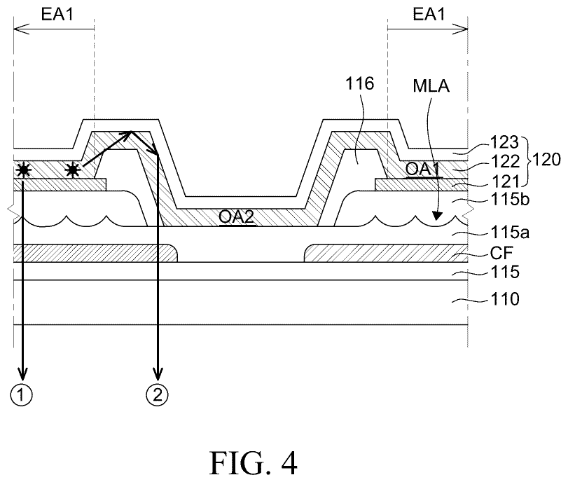

FIG. 4 is a view illustrating a cross-section of a part of a sub-pixel of FIG. 3.

FIG. 3 schematically illustrates cross-sectional structures of the first sub-pixel SP1, the second sub-pixel SP2, and the third sub-pixel SP3 and a planar structure corresponding to the second sub-pixel SP2.

FIG. 4 illustrates a cross-sectional structure of a part of the first sub-pixel SP1 and the second sub-pixel SP2 illustrated in FIG. 3 together with a behavior of emitted light.

In FIGS. 3 and 4, for the convenience of description, a TFT substrate 110 is illustrated by omitting various circuit configurations and wiring lines including a thin film transistor provided on the substrate. Further, even though in FIGS. 3 and 4, components above the light emitting diode 120 are not illustrated for the convenience of description, the present disclosure is not limited thereto and the present disclosure may include an adhesive layer and an encapsulation substrate above the light emitting diode 120.

Further, in FIGS. 3 and 4, a bottom-emission type organic light emitting display device is mainly described, but the present disclosure is not limited thereto and may also be applicable to a top-emission type or a dual-emission type organic light emitting display device.

Referring to FIGS. 3 and 4, the display panel may include a pixel area in which a plurality of sub-pixels SP1, SP2, and SP3 is provided and a peripheral area (not illustrated) in which various circuit configurations and wiring lines are disposed.

A plurality of first sub-pixels SP1, second sub-pixels SP2, and third sub-pixels SP3 may be disposed in the pixel area.

For example, the first sub-pixel SP1 may be a green sub-pixel.

For example, the second sub-pixel SP2 may be a blue sub-pixel.

For example, the third sub-pixel SP3 may be a red sub-pixel.

For example, the first sub-pixel SP1, the second sub-pixel SP2, and the third sub-pixel SP3 may have a circular shape or a polygonal shape, but are not limited thereto. Here, a shape of the sub-pixels SP1, SP2, and SP3 is defined by the shape of the first electrode (anode) 121, but it is not limited thereto.

Even though it is not illustrated in the drawing, the TFT substrate 110 may include various circuit configurations and wiring lines including a thin film transistor provided on the substrate.

For example, a driving transistor and a switching transistor may be disposed above the substrate.

A protection layer 115 may be disposed on the TFT substrate 110 on which various circuit configurations and the wiring lines are disposed.

For example, the protection layer 115 is configured by silicon oxide (SiOx), silicon nitride (SiNx), or a double layered structure thereof, but it is not limited thereto and may be configured by an organic material such as acrylic-based resin or epoxy-based resin.

A color filter layer CF may be disposed on the protection layer 115.

The color filter layer CF of each sub-pixel SP1, SP2, SP3 may have any one color of red, green, and blue. Further, in a sub-pixel in which white is implemented, the color filter layer CF may not be disposed. Red, green, and blue may be disposed in various forms.

The color filter layer CF is disposed in each of the plurality of sub-pixels SP1, SP2, and SP3 or may be disposed only in some sub-pixel SP1, SP2, SP3, among the plurality of sub-pixels SP1, SP2, and SP3.

The color filter layer CF may be disposed in a position corresponding to an emission area EA1 of each sub-pixel SP1, SP2, SP3. The emission area EA1 refers to an area in which an emission layer of the organic layer 122 emits light by the first electrode (that is, an anode) 121 and the second electrode (that is, a cathode) 123.

In the plan view, the color filter layer CF may have an approximately (or totally) rectangular frame shape, but is not limited thereto. Further, in the plan view, the color filter layer CF may have an area larger than the emission area EA1.

Planarization layers 115a and 115b are disposed above the color filter layer CF. For example, the planarization layers 115a and 115b may include a first planarization layer 115a and a second planarization layer 115b. The planarization layers 115a and 115b may be overcoat layers.

The first planarization layer 115a is disposed above the protection layer 115.

The second planarization layer 115b may be disposed on the first planarization layer 115a.

For example, the first planarization layer 115a and the second planarization layer 115b may be configured by an organic material, such as acrylic resin including photo acryl or epoxy resin.

For example, the first planarization layer 115a is disposed on a front surface of the TFT substrate 110 and the second planarization layer 115b is patterned for every sub-pixel SP1, SP2, SP3. That is, a reflection hole OA2 which encloses the emission area EA1 may be disposed in the vicinity of the emission area EA1 of each sub-pixel SP1, SP2, SP3. For example, the reflection hole OA2 may be formed in the bank 116 and the second planarization layer 115b, but is not limited thereto. The reflection hole OA2 allows the cathode 123 which covers the reflection hole OA2 to serve as a reflective electrode to reflect light emitted from the emission layer so as not to be emitted to the adjacent sub-pixels SP1, SP2, and SP3, thereby improving light extraction efficiency. Among light \textcircled{1} and \textcircled{2} emitted from the emission layer, most of light \textcircled{1} is extracted to the outside via the color filter layer CF and the TFT substrate 110. Some light \textcircled{2} is reflected by a reflective electrode (or a mirror) of the cathode 123 disposed in the reflection hole OA2 to be extracted to the outside via the color filter layer CF and the TFT substrate 110. For example, some light \textcircled{2} passes through the emission layer and is reflected by the reflective electrode of the cathode 123 disposed in the reflection hole OA2 to be extracted to the outside. The light \textcircled{2} contributes to light extraction of a non-emission unit in a wave guide mode of the emission layer and a substrate mode of the planarization layers 115a and 115b. As described above, the reflection hole OA2 is disposed so as to completely enclose the emission area EA1 to additionally discharge light in the emission area EA1 of each sub-pixel SP1, SP2, SP3, thereby improving an extraction efficiency of light. However, according to the first example embodiment of the present disclosure, in order to form the reflection hole OA2, a tapered area of the bank 116 is necessary, which causes the reduction in the aperture ratio.

Further, in the plan view, the second planarization layer 115b may have an approximately (or overall) rectangular shape, but is not limited thereto. Further, in the emission area EA1 of each sub-pixel SP1, SP2, SP3, a micro lens array MLA may be disposed to increase the light extraction efficiency of the emission layer. The micro lens array MLA is referred to as a light scattering layer, a micro lens, a nano pattern, a diffuse pattern, a silica bead, or out-coupling structure.

For example, the micro lens array MLA may be provided on a top surface of the first planarization layer 115a.

The micro lens array MLA may have a plurality of concave shapes or convex shapes. For example, the plurality of concave shapes or convex shapes may be a semi-spherical shape or a semi-elliptical shape, but is not limited thereto.

According to the first example embodiment of the present disclosure, the micro lens array MLA is provided on interfaces of the planarization layers 115a and 115b having different refractive indexes to contribute to the light extraction efficiency. For example, the micro lens array MLA is provided on interfaces of the first planarization layer 115a having a low refractive index (˜1.46) and the second planarization layer 115b having a high refractive index (˜1.63) to contribute to the substrate mode light extraction of light \textcircled{1} emitted from the emission layer.

As described above, according to the first example embodiment of the present disclosure, the micro lens array MLA is disposed in a position corresponding to the emission area EA1 of each sub-pixel SP1, SP2, SP3 so that light emitted from the light emitting diode 120 is further extracted to the outside of the display device.

Further, according to the first example embodiment of the present disclosure, the micro lens array MLA is provided in the emission area EA1 which is spaced apart from an end of the second planarization layer 115b by a predetermined distance, rather than on the front surface of the TFT substrate 110. When the micro lens array MLA extends to the interface of the reflection hole OA2, the taper of the bank 116 is increased at the boundary of the reflection hole OA2, that is, in the tapered area of the bank 116. Further, an area between the second planarization layer 115b and the cathode 123 is weakened so that oxygen may be introduced, which may cause a defect. To the contrary, according to the first example embodiment of the present disclosure, the micro lens array MLA is disposed only in the emission area EA1 so that the above-described defect may be suppressed.

In the plan view, the micro lens array MLA may have an area larger than the emission area EA1. Further, in the plan view, the micro lens array MLA may have an approximately (or overall) rectangular shape, but is not limited thereto.

In the meantime, for example, the bank 116 includes an open area OA1 obtained by removing (opening) a part corresponding to the emission area EA1 of each of the sub-pixels SP1, SP2, and SP3.

In the plan view, the opening area OA1 may have an approximately (or overall) rectangular shape, but is not limited thereto.

In the plan view, the bank 116 may have an approximately (or overall) rectangular shape excluding the opening area OA1, but is not limited thereto.

The bank 116 includes a top surface, a first side portion, and a second side portion.

At this time, the top surface of the bank 116 is a surface located at the top of the bank 116 and is substantially parallel to the TFT substrate 110.

The first and second side portions of the bank 116 are surfaces extending from the top surface of the bank 116 to side surfaces. The first and second side portions of the bank 116 may have a predetermined taper angle. The first side portion of the bank 116 corresponds to a boundary of the reflection hole OA2 and the second side portion corresponds to a boundary of the opening area OA1.

For example, the anode 121 is disposed in a part of the top surface of the second planarization layer 115b. A part of the end of the anode 121 is covered by the bank 116. A part of the anode 121 which is not covered by the bank 116 to be exposed may configure the emission area EA1. That is, a part of the bank 116 corresponding to the emission area EA1 of the sub-pixels SP1, SP2, and SP3 may be open. According to the first example embodiment of the present disclosure, in the plan view, the emission area EA1 may have the smallest planar size among the anode 121, the micro lens array MLA, the second planarization layer 115b, the bank 116, and the color filter layer CF. Here, the planar size may be an area. For example, the anode 121 may be formed of a transparent conductive material, such as indium tin oxide (ITO), indium zin oxide (IZO), or indium gallium zinc oxide (IGZO).

An edge of the bank 116 may have the rectangular shape, like the edge of the opening area OA1, but the present disclosure is not limited thereto.

For example, the organic layer 122 may be disposed on the front surface of the TFT substrate 110, including the opening area OA1 and the reflection hole OA2 of the bank 116.

The organic layer 122 may be disposed on the top surface and the first and second side portions of the bank 116, in addition to the opening area OA1 and the reflection hole OA2. The cathode 123 is disposed on the organic layer 122.

The cathode 123 may include a reflective electrode or a reflective material. For example, the cathode 123 may include any one of a group consisting of metal materials, such as gold (Au), silver (Ag), aluminum (Al), molybdenum (Mo), palladium (Pd), copper (Cu), or magnesium (Mg), or an alloy thereof. Alternatively, the cathode 123 may be configured by laminating a layer formed of a transparent conductive layer such as indium tin oxide (ITO), indium zinc oxide (IZO), or indium gallium zinc oxide (IGZO) and a layer formed of a metal material such as gold (Au), silver (Ag), aluminum (Al), molybdenum (Mo), magnesium (Mg), palladium (Pd), copper (CU), or an alloy thereof, but is not limited thereto.

The light emitting diode 120 may be configured by the anode 121, the organic layer 122, and the cathode 123.

An encapsulation substrate is disposed above the TFT substrate 110 in which the light emitting diode 120 is disposed with an adhesive layer interposed therebetween. However, it is not limited thereto and a multilayered encapsulation structure configured by an encapsulation member and a reinforcement substrate may be disposed above the TFT substrate 110.

In the meantime, according to the present disclosure, instead of the bank, the anode extends to the side surface of the second planarization layer to be utilized as an internal total reflection area so that the aperture ratio is increased and the light extraction efficiency is improved, which will be described in detail with reference to the drawings.

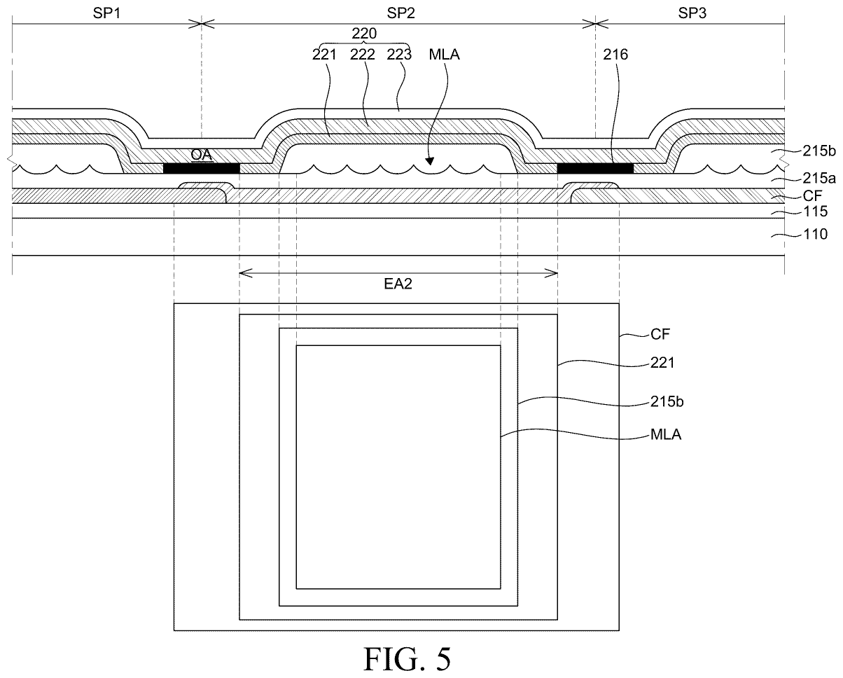

FIG. 5 is a view illustrating a cross-sectional structure and a planar structure of a display panel according to a second example embodiment of the present disclosure.

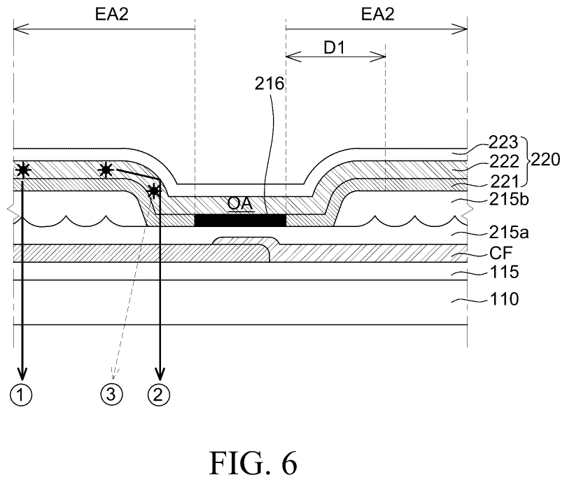

FIG. 6 is a view illustrating a cross-section of a part of a sub-pixel of FIG. 5.

A second example embodiment of the present disclosure of FIGS. 5 and 6 has the substantially same configurations as the first example embodiment of FIGS. 3 and 4 described above except that instead of the bank, an anode 221 extend to a side surface of a second planarization layer 215b and a light shielding layer 216 is formed below the reflection hole OA. Therefore, a redundant description will be omitted. The same configuration will be denoted with the same reference numeral. Here, the description for the same reference numeral may refer to FIGS. 1 to 4.

FIG. 5 schematically illustrates cross-sectional structures of a first sub-pixel SP1, a second sub-pixel SP2, and a third sub-pixel SP3 and a planar structure corresponding to the second sub-pixel SP2.

FIG. 6 illustrates a cross-sectional structure of a part of the first sub-pixel SP1 and the second sub-pixel SP2 illustrated in FIG. 5 together with a behavior of emitted light.

In FIGS. 5 and 6, for the convenience of description, a TFT substrate 110 is illustrated by omitting various circuit configurations and wiring lines including a thin film transistor provided on the substrate. Even though in FIGS. 5 and 6, components above the light emitting diode 220 are not illustrated for the convenience of description, the present disclosure is not limited thereto and the present disclosure includes an adhesive layer and an encapsulation substrate above the light emitting diode 220.

Further, in FIGS. 5 and 6, a bottom-emission type organic light emitting display device is mainly described, but is not limited thereto.

Referring to FIGS. 5 and 6, the display panel includes a pixel area in which a plurality of sub-pixels SP1, SP2, and SP3 is provided and a peripheral area (not illustrated) in which various circuit configurations and wiring lines are disposed.

A plurality of first sub-pixels SP1, second sub-pixels SP2, and third sub-pixels SP3 are disposed in the pixel area.

For example, the first sub-pixel SP1 may be a green sub-pixel.

For example, the second sub-pixel SP2 may be a blue sub-pixel.

For example, the third sub-pixel SP3 may be a red sub-pixel.

For example, the first sub-pixel SP1, the second sub-pixel SP2, and the third sub-pixel SP3 may have a circular shape or a polygonal shape, but are not limited thereto. Here, a shape of the sub-pixels SP1, SP2, and SP3 is defined by the shape of the first electrode (anode) 221, but it is not limited thereto.

Even though it is not illustrated in the drawing, the TFT substrate 110 includes various circuit configurations and wiring lines including a thin film transistor provided on the substrate.

A protection layer 115 is disposed on the TFT substrate 110 on which various circuit configurations and the wiring lines are disposed.

A color filter layer CF is disposed on the protection layer 115.

The color filter layer CF of each sub-pixel SP1, SP2, SP3 may have any one color of red, green, and blue. Further, in a sub-pixel in which white is implemented, the color filter layer CF may not be disposed. Red, green, and blue may be disposed in various forms.

The color filter layer CF is disposed in each of the plurality of sub-pixels SP1, SP2, and SP3 or is disposed only in some sub-pixel SP1, SP2, SP3, among the plurality of sub-pixels SP1, SP2, and SP3.

The color filter layer CF extend to the boundary between the sub-pixels SP1, SP2, and SP3, including an emission area EA2 of each sub-pixel SP1, SP2, SP3. The emission area EA2 refers to an area in which the emission layer of the organic layer 222 emits light by the anode 221 and the cathode 223. According to the second example embodiment of the present disclosure, the anode 221 extends to a part of the top surface of the first planarization layer 215a, including a side surface of the second planarization layer 215b. Further, the bank is removed so that the aperture ratio is increased by the increase of the anode 221 area (increased by a width D1 of FIG. 6) which contributes to the emission, as compared with the first example embodiment. Further, the emission area EA2 is also increased.

According to the second example embodiment of the present disclosure, the color filter layers CF are disposed to overlap each other. For example, parts of the color filter layer CF may overlap each other below the light shielding layer 216, but the present disclosure is not limited thereto.

In the plan view, the color filter layer CF may have an approximately (or overall) rectangular frame shape, but is not limited thereto. Further, in the plan view, the color filter layer CF may have an area larger than the emission area EA2.

Planarization layers 215a and 215b are disposed above the color filter layer CF. For example, the planarization layers 215a and 215b may include a first planarization layer 215a and a second planarization layer 215b. The planarization layers 215a and 215b may be overcoat layers.

The first planarization layer 215a may be disposed above the protection layer 115.

The second planarization layer 215b may be disposed on the first planarization layer 215a.

For example, the first planarization layer 215a may be disposed on a front surface of the TFT substrate 110 and the second planarization layer 215b may be patterned for every sub-pixel SP1, SP2, SP3. That is, a reflection hole OA which encloses the emission area EA2 may be disposed in the vicinity of the emission area EA2 of each sub-pixel SP1, SP2, SP3. For example, the reflection hole OA may be formed in the second planarization layer 215b, but is not limited thereto. The reflection hole OA allows the cathode 223 which covers the reflection hole OA to serve as a reflective electrode to reflect light emitted from the emission layer so as not to be emitted to the adjacent sub-pixels SP1, SP2, and SP3, thereby improving light extraction efficiency. Among light \textcircled{1}, \textcircled{2}, and \textcircled{3} emitted from the emission layer, most of light \textcircled{1} is extracted to the outside via the color filter layer CF and the TFT substrate 110. The other light \textcircled{2} is reflected by a reflective electrode (or a mirror) of the cathode 223 disposed in the reflection hole OA to be extracted to the outside via the color filter layer CF and the TFT substrate 110. For example, some light \textcircled{2} passes through the emission layer and is reflected by the reflective electrode of the cathode 223 disposed in the reflection hole OA, and then extracted to the outside via the extending anode 221. At this time, the light \textcircled{2} may contribute to the non-emission unit light extraction of the above-described wave guide mode and substrate mode. The reflection hole OA is disposed so as to completely enclose the emission area EA2 to additionally discharge light in the emission area EA2 of each sub-pixel SP1, SP2, SP3, thereby improving an extraction efficiency of light. Further, according to the second example embodiment of the present disclosure, the anode 221 is disposed above the first and second planarization layers 215a and 215b so as to cover a side surface of the second planarization layer 215b and (instead of the bank), the tapered area of the second planarization layer 215b is also used as the opening. Therefore, the light extraction efficiency may be improved with the increase in the aperture ratio. According to the second example embodiment of the present disclosure, a bank which covers the end of the anode 221 is not used so that the defect caused by the oxygen inflow described above may be completely suppressed.

According to the second example embodiment of the present disclosure, the anode 221 extends so as to overlap the edge of the reflection hole OA as described above. In this case, among the light \textcircled{1}, \textcircled{2}, and \textcircled{3} emitted from the emission layer, some light \textcircled{3} emitted by the extending anode 221 is extracted to the outside via the anode 221 to contribute to the expansion of the emission area EA2. Here, the emission area EA2 may be configured to the area of the extending anode 221. For example, in the plan view, the emission area EA2 may have the same planar size as the anode 221.

As described above, according to the second example embodiment, as compared with the first example embodiment described above, the aperture ratio is improved and the efficiency may be increased by the emission by the side surface of the extending anode 221.

In the meantime, in the plan view, the second planarization layer 215b may have an approximately (or overall) rectangular shape, but is not limited thereto.

Further, in the emission area EA2 of each sub-pixel SP1, SP2, SP3, a micro lens array MLA may be disposed to increase the light extraction efficiency of the emission layer.

For example, the micro lens array MLA may be provided on a top surface of the first planarization layer 215a.

The micro lens array MLA may have a plurality of concave shapes or convex shapes. For example, the plurality of concave shapes or convex shapes may be a semi-spherical shape or a semi-elliptical shape, but is not limited thereto.

According to the second example embodiment of the present disclosure, the micro lens array MLA is provided on interfaces of the planarization layers 215a and 215b having different refractive indexes to contribute to the substrate mode light extraction of some light \textcircled{1} emitted from the emission layer.

As described above, according to the second example embodiment of the present disclosure, the micro lens array MLA is disposed in a position corresponding to the emission area EA2 of each sub-pixel SP1, SP2, SP3 so that light emitted from the light emitting diode 220 may further be extracted to the outside of the display device.

Further, according to the second example embodiment of the present disclosure, the micro lens array MLA is provided in the emission area EA2 which is spaced apart from an end of the second planarization layer 215b by a predetermined distance, rather than on the front surface of the TFT substrate 110.

In the plan view, the emission area EA2 may have an area larger than the micro lens array MLA and may overlap the anode 221. Further, in the plan view, areas of the micro lens array MLA, the second planarization layer 215b, and the anode 221 are increased in this order. In the plan view, the micro lens array MLA may have an approximately (or overall) rectangular shape.

Further, in the plan view, the color filter layer CF may have an area larger than the anode 221.

As described above, the anode 221 may be disposed to a part of the top surface of the first planarization layer 215a, including the side surface of the second planarization layer 215b. According to the second example embodiment of the present disclosure, a bank is not formed so that a part in which the anode 221 is disposed may configure the emission area EA2.

In the meantime, a light shielding layer 216 may be disposed in a non-emission area between the anodes 221.

For example, the light shielding layer 216 is configured by a black based resin and may serve to suppress the color mixture between the sub-pixels SP1, SP2, and SP3.

Further, for example, the organic layer 222 may be disposed on the front surface of the TFT substrate 110, including the reflection hole OA.

The organic layer 222 may be disposed on the anode 221 and the light shielding layer 216.

The cathode 223 may be disposed on the organic layer 222.

The light emitting diode 220 may be configured by the anode 221, the organic layer 222, and the cathode 223.

An encapsulation substrate may be disposed above the TFT substrate 110 in which the light emitting diode 220 is disposed with an adhesive layer interposed therebetween. However, it is not limited thereto and a multilayered encapsulation structure configured by an encapsulation member and a reinforcement substrate may be disposed above the TFT substrate 110.

In the meantime, the present disclosure is applicable regardless of the placement type of the light shielding layer and the light shielding layer may be formed to cover a part of the anode including an area between the anodes, which will be described in detail with reference to the following drawings.

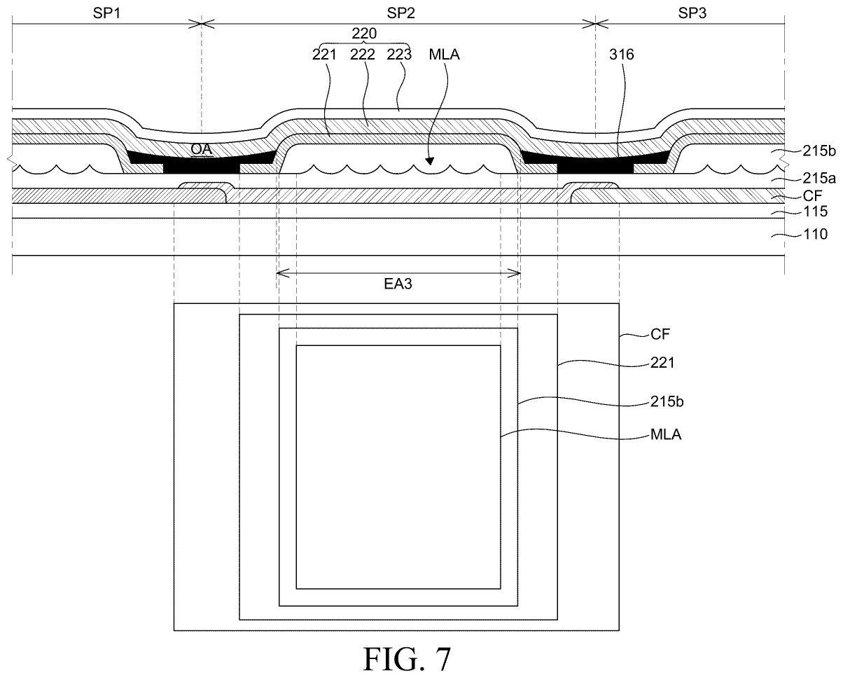

FIG. 7 is a view illustrating a cross-sectional structure and a planar structure of a display panel according to a third example embodiment of the present disclosure.

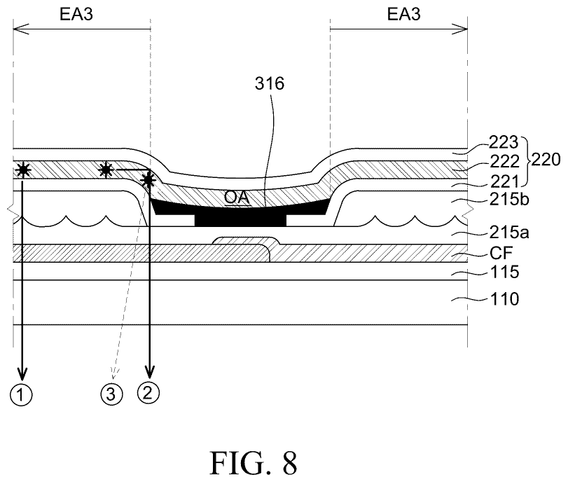

FIG. 8 is a view illustrating a cross-section of a part of a sub-pixel of FIG. 7.

A third example embodiment of the present disclosure of FIGS. 7 and 8 has the substantially same configuration as the second example embodiment of the present disclosure of FIGS. 5 and 6 described above except that a light shielding layer 316 is formed so as to cover a part of the anode 221. Therefore, a redundant description will be omitted. The same configuration will be denoted with the same reference numeral. Here, the description for the same reference numeral may refer to FIGS. 1 to 6.

FIG. 7 schematically illustrates cross-sectional structures of the first sub-pixel SP1, the second sub-pixel SP2, and the third sub-pixel SP3 and a planar structure corresponding to the second sub-pixel SP2.

FIG. 8 illustrates a cross-sectional structure of a part of the first sub-pixel SP1 and the second sub-pixel SP2 illustrated in FIG. 7 together with a behavior of emitted light.

In FIGS. 7 and 8, for the convenience of description, a TFT substrate 110 is illustrated by omitting various circuit configurations and wiring lines including a thin film transistor provided on the substrate. Further, even though in FIGS. 7 and 8, components above the light emitting diode 220 are not illustrated for the convenience of description, the present disclosure is not limited thereto and the present disclosure may include an adhesive layer and an encapsulation substrate above the light emitting diode 220.

Further, in FIGS. 7 and 8, a bottom-emission type organic light emitting display device is mainly described, but is not limited thereto.

Referring to FIGS. 7 and 8, a color filter layer CF may be disposed on the protection layer 115.

The color filter layer CF is disposed in each of the plurality of sub-pixels SP1, SP2, and SP3 or may be disposed only in some sub-pixel SP1, SP2, SP3, among the plurality of sub-pixels SP1, SP2, and SP3.

The color filter layer CF extends to the boundary between the sub-pixels SP1, SP2, and SP3, including the emission area EA3 of each sub-pixel SP1, SP2, SP3 to be disposed. According to a third example embodiment of the present disclosure, the anode 221 extends to a part of the top surface of the first planarization layer 215a, including the side surface of the second planarization layer 215b. However, the light shielding layer 316 is formed to cover a part of the anode 221 so that the emission area EA3 may be smaller than that of the second example embodiment.

The light shielding layer 316 may be disposed so as to cover ends and tapered areas of the anodes 221, including the area between the anodes 221, but is not limited thereto.

Further, according to the third example embodiment of the present disclosure, the color filter layers CF may be disposed to overlap each other. For example, parts of the color filter layer CF may overlap each other below the light shielding layer 316, but the present disclosure is not limited thereto.

The first planarization layer 215a may be disposed above the color filter layer CF.

The second planarization layer 215b may be disposed on the first planarization layer 215a.

For example, the first planarization layer 215a may be disposed on a front surface of the TFT substrate 110 and the second planarization layer 215b may be patterned for every sub-pixel SP1, SP2, SP3. That is, a reflection hole OA which encloses the emission area EA3 may be disposed in the vicinity of the emission area EA3 of each sub-pixel SP1, SP2, SP3. For example, the reflection hole OA may be formed in the second planarization layer 215b, but is not limited thereto. Among light \textcircled{1}, \textcircled{2}, and \textcircled{3} emitted from the emission layer, most of light \textcircled{1} is extracted to the outside via the color filter layer CF and the TFT substrate 110. Some light \textcircled{2} is reflected by a reflective electrode of the cathode 223 disposed in the reflection hole OA to be extracted to the outside via the color filter layer CF and the TFT substrate 110. For example, some light (2) passes through the emission layer and is reflected by the reflective electrode of the cathode 223 disposed in the reflection hole OA, and then extracted to the outside via the extending anode 221.

Further, according to the third example embodiment of the present disclosure, similar to the second example embodiment described above, the anode 221 is disposed above the first and second planarization layers 215a and 215b so as to cover a side surface of the second planarization layer 215b and the tapered area of the second planarization layer 215b may also be used as the opening.

According to the third example embodiment of the present disclosure, the anode 221 extends so as to overlap the edge of the reflection hole OA as described above. As the light shielding layer 316 is formed so as to cover a part of the anode, for example, an end and a part of a tapered area of the anode 221, some of light \textcircled{3} emitted by a part of the anode 221 which is not covered by the light shielding layer 316, among the parts of the extending anode 221, is extracted to the outside via the anode 221. The part of the anode 221 of each sub-pixel SP1, SP2, SP3 which is not covered by the light shielding layer 316 may configure the emission area EA3.

In the plan view, the emission area EA3 of the third example embodiment of the present disclosure may have an area larger than that of the micro lens array MLA. Further, in the plan view, the emission area EA3 may overlap the second planarization layer 215b or may have a larger area than the second planarization layer 215b. Areas of the anode 221 and the color filter layer CF are increased larger than the micro lens array MLA in that order.

As described above, according to the third example embodiment of the present disclosure, the anode 221 extends to a part of the top surface of the first planarization layer 215a, including the side surface of the second planarization layer 215b. Further, according to the third example embodiment, a light shielding layer 316 may be disposed so as to cover ends and a part of the tapered areas the anodes 221, including an area between the anodes 221. In this case, a thickness and a width of the light shielding layer 316 are increased as compared with the second example embodiment so that it is advantageous to suppress the color mixture and an interval between the sub-pixels SP1, SP2, and SP3 is adjusted according to a model of the display device to control the color mixture.

In the meantime, the bank is formed between sub-pixels and the anode extends to a top surface of the bank to ensure the open area (emission area) as much as possible, which will be described in detail with reference to the following drawings.

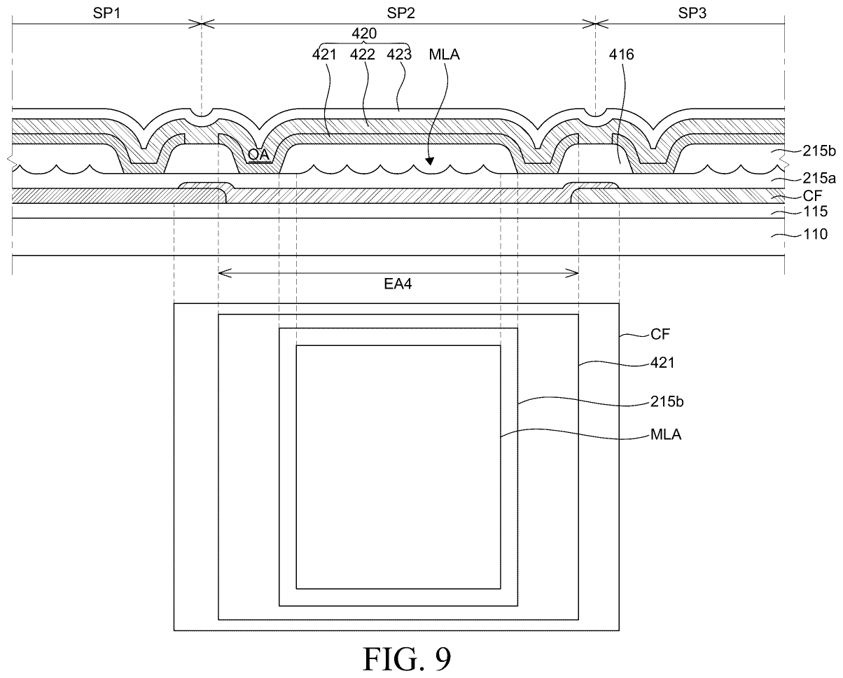

FIG. 9 is a view illustrating a cross-sectional structure and a planar structure of a display panel according to a fourth example embodiment of the present disclosure.

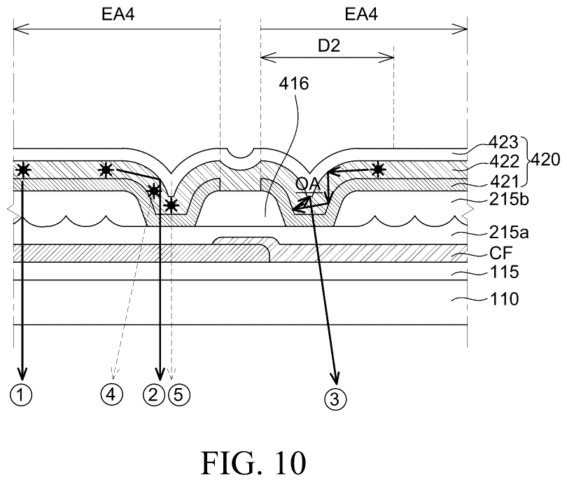

FIG. 10 is a view illustrating a cross-section of a part of a sub-pixel of FIG. 9.

A fourth example embodiment of the present disclosure of FIGS. 9 and 10 has the substantially same configurations as the second example embodiment of FIGS. 5 and 6 described above except that a bank 416 is formed at the boundary between sub-pixels SP1, SP2, and SP3 and an anode 421 extends to a top surface of the bank 416. Therefore, a redundant description will be omitted. The same configuration will be denoted with the same reference numeral. Here, the description for the same reference numeral may refer to FIGS. 1 to 8.

FIG. 9 schematically illustrates cross-sectional structures of a first sub-pixel SP1, a second sub-pixel SP2, and a third sub-pixel SP3 and a planar structure corresponding to the second sub-pixel SP2.

FIG. 10 illustrates a cross-sectional structure of a part of the first sub-pixel SP1 and the second sub-pixel SP2 illustrated in FIG. 9 together with a behavior of emitted light.

In FIGS. 9 and 10, for the convenience of description, a TFT substrate 110 is illustrated by omitting various circuit configurations and wiring lines including a thin film transistor provided on the substrate. Even though in FIGS. 9 and 10, components above the light emitting diode 420 are not illustrated for the convenience of description, the present disclosure is not limited thereto and the present disclosure may include an adhesive layer and an encapsulation substrate above the light emitting diode 420.

Further, in FIGS. 9 and 10, a bottom-emission type organic light emitting display device is mainly described, but is not limited thereto.

Referring to FIGS. 9 and 10, a color filter layer CF may be disposed on the protection layer 115.

The first planarization layer 215a may be disposed above the color filter layer CF.

The second planarization layer 215b may be disposed on the first planarization layer 215a.

For example, the first planarization layer 215a may be disposed on a front surface of the TFT substrate 110 and the second planarization layer 215b may be patterned for every sub-pixel SP1, SP2, SP3. That is, one pair of reflection holes OA which encloses the emission area EA4 may be disposed in the vicinity of the emission area EA4 of each sub-pixel SP1, SP2, SP3.

For example, the second planarization layer 215b between the sub-pixels SP1, SP2, and SP3 is patterned to form one pair of reflection holes OA with the bank 416 therebetween.

For example, the bank 416 may be formed of the same material as the second planarization layer 215b, but is not limited thereto. The bank 416 may have a height different from that of the second planarization layer 215b. For example, the bank 416 may have a height lower than that of the second planarization layer 215b, but is not limited thereto.

According to the fourth example embodiment of the present disclosure, the anode 421 extends to a part of the top surface of the bank 416, including the reflection hole OA. Therefore, as compared with the first example embodiment described above, the aperture ratio may further be increased by the increase of the anode 421 area (increased by a width D2 of FIG. 10) which contributes to the emission. Further, the emission area EA4 may further be increased. The emission area EA4 of the fourth example embodiment is the largest, followed by the second emission area EA2 of the second example embodiment, and then the emission area EA3 of the third example embodiment.

The anode 421 may be in contact with the top surface and the side surface of the second planarization layer 215b, the top surface of the first planarization layer 215a, and a side surface and a part of the top surface of the bank 416.

Further, according to the fourth example embodiment of the present disclosure, the color filter layers CF may be disposed to overlap each other. For example, parts of the color filter layers CF may overlap each other below the bank 416, but the present disclosure is not limited thereto.

In the meantime, among light \textcircled{1}, \textcircled{2}, \textcircled{3}, \textcircled{4}, and \textcircled{5} emitted from the emission layer, most of light \textcircled{1} is extracted to the outside via the color filter layer CF and the TFT substrate 110. Some light \textcircled{2} and \textcircled{3} is reflected by a reflective electrode of the cathode 423 disposed in the reflection hole OA to be extracted to the outside via the color filter layer CF and the TFT substrate 110. For example, some light \textcircled{2} passes through the emission layer and is reflected by the reflective electrode of the cathode 423 disposed in the reflection hole OA, and then extracted to the outside via the extending anode 421. Further, for example, the other light \textcircled{3} passes through the emission layer and is reflected by the reflective electrode of the cathode 423 disposed in the reflection hole OA, and then reflected by the extending anode 421 and the reflective electrode of the cathode 423 to be extracted to the outside via the extending anode 421.

According to the fourth example embodiment, the light extraction efficiency may be maximized by the anode 421 which extends to a top surface of the bank 416. That is, for example, according to the fourth example embodiment of the present disclosure, the anode 421 is disposed so as to cover the top surface and the side surface of the second planarization layer 215b, a part of the top surface of the first planarization layer 215a, and a side surface and a part of the top surface of the bank 416. The second planarization layer 215b and the tapered area of the bank 416 may also be used as an opening. As described above, according to the fourth example embodiment of the present disclosure, the anode 421 may extend to a part of the top surface of the bank 416 to be filled in the reflection hole OA. In this case, among light \textcircled{1}, \textcircled{2}, \textcircled{3}, \textcircled{4}, and \textcircled{5} emitted from the emission layer, some light \textcircled{4} and \textcircled{5} emitted by the extending anode 421 may be extracted to the outside via the extending anode 421.

As described above, according to the fourth example embodiment, as compared with the first, second, and third example embodiments described above, the aperture ratio is further improved and the efficiency may further be increased by the emission by the extending anode 421. The anode 421 which extends to the top surface of the bank 416 may configure the emission area EA4 of each sub-pixel SP1, SP2, SP3. In the plan view, the emission area EA4 has a larger area, excluding the color filter layer CF, for example, may have a larger area than those of the micro lens array MLA and the second planarization layer 215b. For example, in the plan view, the emission area EA4 may have the same planar size as the anode 421.

In the meantime, according to the present disclosure, a light shielding layer is formed between the sub-pixels and the anode may extend to the top surface of the light shielding layer, which will be described in detail with the following drawing.

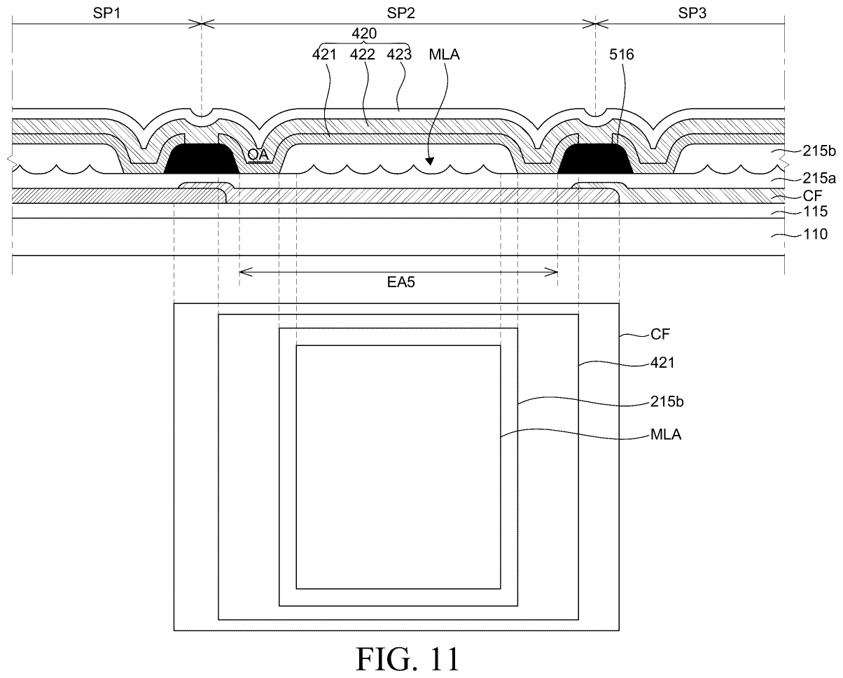

FIG. 11 is a view illustrating a cross-sectional structure and a planar structure of a display panel according to a fifth example embodiment of the present disclosure.

A fifth example embodiment of the present disclosure of FIG. 11 has the substantially same configuration as the fourth example embodiment of the present disclosure of FIGS. 9 and 10 described above except that a light shielding layer 516 is applied, instead of the bank so that a redundant description will be omitted. The same configuration will be denoted with the same reference numeral. Here, the description for the same reference numeral may refer to FIGS. 1 to 10.

FIG. 11 schematically illustrates cross-sectional structures of the first sub-pixel SP1, the second sub-pixel SP2, and the third sub-pixel SP3 and a planar structure corresponding to the second sub-pixel SP2.

In FIG. 11, for the convenience of description, a TFT substrate 110 is illustrated by omitting various circuit configurations and wiring lines including a thin film transistor provided on the substrate. Further, even though in FIG. 11, components above the light emitting diode 420 are not illustrated for the convenience of description, the present disclosure is not limited thereto and the present disclosure may include an adhesive layer and an encapsulation substrate above the light emitting diode 420. Further, in FIG. 11, a bottom-emission type organic light emitting display device is mainly described, but is not limited thereto.

Referring to FIG. 11, a color filter layer CF may be disposed on the protection layer 115.

The first planarization layer 215a may be disposed above the color filter layer CF.

The second planarization layer 215b may be disposed on the first planarization layer 215a.

For example, the first planarization layer 215a is disposed on a front surface of the TFT substrate 110 and the second planarization layer 215b may be patterned for every sub-pixel SP1, SP2, SP3. That is, one pair of reflection holes OA may be disposed in the vicinity of an emission area EA5 of each sub-pixel SP1, SP2, SP3 along an edge of the emission area EA5. An anode 421 area which does not overlap the light shielding layer 516 may configure the emission area EA5. In the plan view, the emission area EA5 has a smaller area than the entire area of the anode 421 and the areas of the micro lens array MLA, the second planarization layer 215b, the emission area EA5, and the anode 421 are increased in this order.

For example, the second planarization layer 215b between the sub-pixels SP1, SP2, and SP3 are patterned to form one pair of reflection holes OA with the light shielding layer 516 therebetween.

For example, the light shielding layer 516 may be formed of a black based resin, but is not limited thereto. The light shielding layer 516 has a height different from that of the second planarization layer 215b. For example, the light shielding layer 516 may have a height lower than that of the second planarization layer 215b, but is not limited thereto. The light shielding layer 516 may serve to suppress the color mixture between the sub-pixels SP1, SP2, and SP3.

According to the fifth example embodiment of the present disclosure, the anode 421 may extend to a part of the top surface of the light shielding layer 516, including a reflection hole OA.

The anode 421 may be in contact with the top surface and the side surface of the second planarization layer 215b, the top surface of the first planarization layer 215a, and a side surface and a part of the top surface of the light shielding layer 516.

As substantially the same as the fourth example embodiment, according to the fifth example embodiment of the present disclosure, the anode 421 is disposed so as to cover the top surface and the side surface of the second planarization layer 215b, a part of the top surface of the first planarization layer 215a, and a side surface and a part of the top surface of the light shielding layer 516. The second planarization layer 215b and the tapered area of the light shielding layer 516 may also be used as an opening.

Further, according to the fifth example embodiment of the present disclosure, the color filter layers CF may be disposed to overlap each other. For example, parts of the color filter layer CF may overlap each other below the light shielding layer 516, but the present disclosure is not limited thereto.

The example embodiments of the present disclosure can also be described as follows:

According to an aspect of the present disclosure, there is provided a display device. The display device includes a substrate, a plurality of sub-pixels each including an emission area, a first planarization layer disposed above the substrate, a second planarization layer which is disposed on the first planarization layer, excluding a reflection hole which exposes the first planarization layer, where the second planarization layer is patterned for every sub-pixel, an anode which covers at least a part of the exposed first planarization layer and at least a part of the second planarization layer, a light shielding layer which covers a remaining part of the exposed first planarization layer, an organic layer disposed on the anode and the light shielding layer and a cathode disposed on the organic layer.

The anode may overlap an edge of the reflection hole.

The anode may be in contact with a top surface and a side surface of the second planarization layer and a part of a top surface of the exposed first planarization layer.

The light shielding layer may comprise a black based resin and may be disposed in a non-emission area between the anodes.

The light shielding layer may extend to cover an edge and a part of a tapered area of the anode, including an area between the anodes.

The display device may further comprise a color filter layer disposed below the first planarization layer, the color filter layer may extend to a boundary between the plurality of sub-pixels, including the emission area of each sub-pixel.

Parts of the color filter layer may overlap each other below the light shielding layer.

According to another aspect of the present disclosure, there is provided a display device. The display device includes a substrate, a plurality of sub-pixels each including an emission area, a first planarization layer disposed above the substrate, a bank disposed on the first planarization layer of a non-emission area, a second planarization layer which is disposed on the first planarization layer, is spaced apart from the bank, and is patterned for every sub-pixel, a reflection hole which exposes the first planarization layer between the bank and the second planarization layer, an anode which covers the exposed first planarization layer, a side surface and a part of a top surface of the bank, and a side surface and a top surface of the second planarization layer, an organic layer which is disposed on the anode and a remaining part of the top surface of the bank and a cathode disposed on the organic layer.

The anode may be in contact with the top surface and the side surface of the second planarization layer, a top surface of the first planarization layer, and the side surface and the part of the top surface of the bank.

The bank may comprise a same material as the second planarization layer and may have a height lower than the second planarization layer.

The bank may comprise a black based resin.

The display device may further comprise a color filter layer disposed below the first planarization layer, the color filter layer may extend to a boundary between the plurality of sub-pixels, including the emission area of each sub-pixel.

Parts of the color filter layer may overlap each other below the bank.

The anode may comprise a transparent conductive material and the cathode may include a reflective electrode or a reflective material.

A top surface of the first planarization layer may have a plurality of concave shapes or convex shapes.

The first planarization layer and the second planarization layer may have different refractive indexes.

The plurality of concave shapes or convex shapes may configure a micro lens array and the micro lens array may be disposed in a position corresponding to the emission area of a corresponding sub-pixel of the plurality of sub-pixels.

The micro lens array may be disposed to be spaced apart from an edge of the second planarization layer by a predetermined distance.

The reflection hole may be disposed to enclose the emission area in a vicinity of the emission area of a corresponding sub-pixel of the plurality of sub-pixels.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure. The scope of protection of the present disclosure should be construed based on the following claims, and all technical features within the scope of equivalents thereof should be construed as being included within the scope of the present disclosure.

What is claimed is:

1. A display device, comprising:
a substrate;
a plurality of sub-pixels, each of the plurality of sub-pixels including an emission area;
a first planarization layer disposed above the substrate;
a second planarization layer which is disposed on the first planarization layer, excluding a reflection hole which exposes the first planarization layer, wherein the second planarization layer is patterned for every sub-pixel;
an anode which covers at least a part of the exposed first planarization layer and at least a part of the second planarization layer;
a light shielding layer which covers a remaining part of the exposed first planarization layer;
an organic layer disposed on the anode and the light shielding layer; and
a cathode disposed on the organic layer.

2. The display device according to claim 1, wherein the anode overlaps an edge of the reflection hole.

3. The display device according to claim 1, wherein the anode is in contact with a top surface and a side surface of the second planarization layer and a part of a top surface of the exposed first planarization layer.

4. The display device according to claim 1, wherein the light shielding layer comprises a black based resin and is disposed in a non-emission area between anodes.

5. The display device according to claim 4, wherein the light shielding layer extends to cover an edge and a part of a tapered area of the anode, including an area between the anodes.

6. The display device according to claim 1, further comprising:
a color filter layer disposed below the first planarization layer,
wherein the color filter layer extends to a boundary between the plurality of sub-pixels, including the emission area of each sub-pixel.

7. The display device according to claim 6, wherein parts of the color filter layer overlap each other below the light shielding layer.

8. A display device, comprising:
a substrate;
a plurality of sub-pixels, each of the plurality of sub-pixels including an emission area;
a first planarization layer disposed above the substrate;
a bank disposed on the first planarization layer of a non-emission area;
a second planarization layer which is disposed on the first planarization layer, is spaced apart from the bank, and is patterned for every sub-pixel;
a reflection hole which exposes the first planarization layer between the bank and the second planarization layer;
an anode which covers the exposed first planarization layer, a side surface and a part of a top surface of the bank, and a side surface and a top surface of the second planarization layer;
an organic layer which is disposed on the anode and a remaining part of the top surface of the bank; and
a cathode disposed on the organic layer.

9. The display device according to claim 8, wherein the anode is in contact with the top surface and the side surface of the second planarization layer, a top surface of the first planarization layer, and the side surface and the part of the top surface of the bank.

10. The display device according to claim 8, wherein the bank comprises a same material as the second planarization layer and has a height lower than the second planarization layer.

11. The display device according to claim 8, wherein the bank comprises a black based resin.

12. The display device according to claim 8, further comprising:
a color filter layer disposed below the first planarization layer,
wherein the color filter layer extends to a boundary between the plurality of sub-pixels, including the emission area of each sub-pixel.

13. The display device according to claim 12, wherein parts of the color filter layer overlap each other below the bank.

14. The display device according to claim 1, wherein the anode comprises a transparent conductive material, and
wherein the cathode includes a reflective electrode or a reflective material.

15. The display device according to claim 14, wherein a top surface of the first planarization layer has a plurality of concave shapes or convex shapes.

16. The display device according to claim 14, wherein the first planarization layer and the second planarization layer have different refractive indexes.

17. The display device according to claim 15, wherein the plurality of concave shapes or convex shapes configures a micro lens array, and the micro lens array is disposed in a position corresponding to the emission area of a corresponding sub-pixel of the plurality of sub-pixels.

18. The display device according to claim 17, wherein the micro lens array is disposed to be spaced apart from an edge of the second planarization layer by a predetermined distance.

19. The display device according to claim 14, wherein the reflection hole is disposed to enclose the emission area in a vicinity of the emission area of a corresponding sub-pixel of the plurality of sub-pixels.
